(19) United States
(12) Patent Application Publication
(10) Pub. No.: US 2016/0163800 A1
(43) Pub. Date: Jun. 9, 2016

(54) SEMICONDUCTOR DEVICE AND METHOD OF MANUFACTURING THE SAME

(71) Applicant: Sumitomo Electric Industries, Ltd., Osaka-shi (JP)

(72) Inventor: Mitsuhiko Sakai, Osaka-shi (JP)

(21) Appl. No.: 14/903,424

(22) PCT Filed: May 28, 2014
(86) PCT No.: PCT/JP2014/064112

§ 371 Date: Jan. 7, 2016

(30) Foreign Application Priority Data
Jul. 12, 2013 (JP) 2013-146695

(51) Int. Cl. H01L 29/16; H01L 23/31; H01L 23/29; H01L 21/78; H01L 29/872; H01L 29/739; H01L 21/04; H01L 21/02; H01L 29/06; H01L 29/78

(52) U.S. Cl. CPC H01L 29/1608; H01L 29/0619; H01L 23/3171; H01L 23/291; H01L 23/3192; H01L 29/7802; H01L 29/872; H01L 29/7395; H01L 21/0475; H01L 21/0485; H01L 21/02164; H01L 21/0217; H01L 21/78

(57) ABSTRACT

A semiconductor layer having an upper surface and an end surface intersecting with the upper surface, an upper electrode (source electrode) formed on the upper surface and electrically connected to the semiconductor layer, and a protecting film extending from over at least a portion of the upper surface to over at least a portion of the end surface are provided.

### TECHNICAL FIELD

The present invention relates to semiconductor devices and methods of manufacturing the same, and more particularly to a semiconductor device required to have a high breakdown voltage and a method of manufacturing the same.

### BACKGROUND ART

In recent years, silicon carbide has been increasingly employed as a material forming a semiconductor device such as a MOSFET (Metal Oxide Semiconductor Field Effect Transistor) in order to allow for higher breakdown voltage, lower loss, the use in a high-temperature environment and the like of the semiconductor device. Silicon carbide is a wide band gap semiconductor having a band gap wider than that of silicon which has been conventionally and widely used as a material forming a semiconductor device. By employing the silicon carbide as a material forming a semiconductor device, therefore, higher breakdown voltage, lower on-resistance and the like of the semiconductor device can be achieved. A semiconductor device made of silicon carbide is also advantageous in that performance degradation is small when used in a high-temperature environment as compared to a semiconductor device made of silicon.

For example, WO 2011/027523 discloses a semiconductor device in which a protective insulating film made of silicon nitride and having a thickness of 1.5 μm or more is formed on a main surface of a guard ring region arranged to surround a semiconductor element region in a silicon carbide layer.

### CITATION LIST

### Patent Document

PTD 1: WO 2011/027523

### SUMMARY OF INVENTION

### Technical Problem

In the semiconductor device described in WO 2011/027523, however, in order to further increase the breakdown voltage, the size of the main surface of the guard ring region covered with the protective insulating film needs to be increased. Here, in order to maintain the size of the semiconductor element region, the size of the semiconductor device needs to be increased. Unfortunately, such increase in size of the semiconductor device results in increased costs to manufacture the semiconductor device.

The present invention has been made to solve the problem as described above. A main object of the present invention is to provide a semiconductor device capable of achieving an improved breakdown voltage without an increase in size, and a method of manufacturing the same.

### Solution to Problem

A semiconductor device according to the present invention includes a semiconductor layer having an upper surface and an end surface intersecting with the upper surface, an upper electrode formed on the upper surface and electrically connected to the semiconductor layer, and a protecting film extending from over at least a portion of the upper surface to over at least a portion of the end surface.

### Advantageous Effects of Invention

According to the present invention, a semiconductor device capable of achieving an improved breakdown voltage without an increase in size, and a method of manufacturing the same can be provided.

### BRIEF DESCRIPTION OF DRAWINGS

FIG. 1 is a cross-sectional view illustrating a semiconductor device according to a first embodiment.

FIG. 2 is a top view of the semiconductor device according to the first embodiment.

FIG. 3 is a flowchart of a method of manufacturing the semiconductor device according to the first embodiment.

FIG. 4 is a cross-sectional view illustrating the method of manufacturing the semiconductor device according to the first embodiment.

FIG. 5 is a cross-sectional view illustrating the method of manufacturing the semiconductor device according to the first embodiment.

FIG. 6 is a cross-sectional view illustrating a semiconductor device and a method of manufacturing the same according to a second embodiment.

FIG. 7 is a cross-sectional view illustrating a semiconductor device and a method of manufacturing the same according to a third embodiment.

### DESCRIPTION OF EMBODIMENTS

### Description of Embodiments of the Present Invention

A summary of embodiments of the present invention will be initially listed.

(1) A semiconductor device according to an embodiment of the present invention includes a semiconductor layer 10 having an upper surface 10a and an end surface 5c intersecting with upper surface 10a, an upper electrode (a source electrode 16) formed on upper surface 10a and electrically connected to semiconductor layer 10, and a protecting film 1 extending from over at least a portion of upper surface 10a to over at least a portion of end surface 5c.

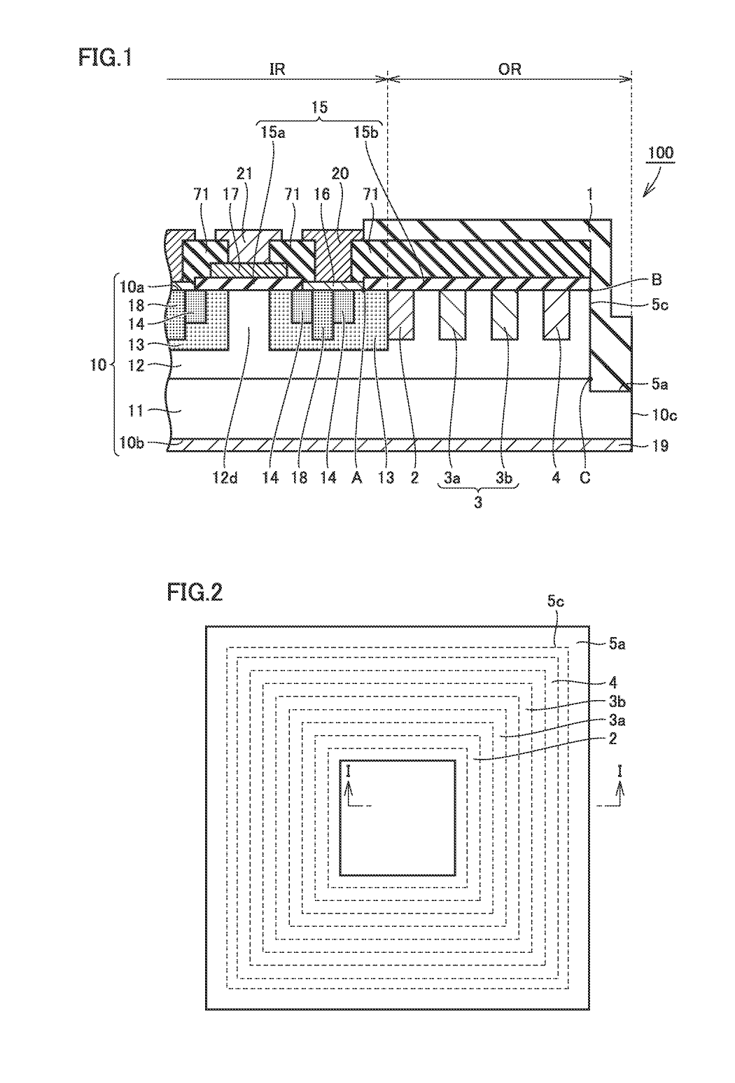

In this configuration, with protecting film 1 extending from over at least a portion of upper surface 10a to over at least a portion of end surface 5c, the distance from the upper electrode (source electrode 16) to an outer peripheral edge of a region covered with protecting film 1 in semiconductor layer 10 can be increased, as compared to a semiconductor device having the same size and having the protecting film formed only on a portion of the upper surface. By increasing this distance, the intensity of an electric field generated in semiconductor layer 10 when a voltage is applied between a source and a drain of a MOSFET 100 can be suppressed. Thus, in the semiconductor device according to this embodiment, by increasing the aforementioned distance as compared to a semiconductor device having the protecting film formed only on the upper surface of the semiconductor layer, electric field concentration in semiconductor layer 10, or electric field concentration in an interface between semiconductor layer 10 and an oxide film (an insulating film portion 15b in FIG. 1) can be alleviated. As a result, a maximum electric field intensity in semiconductor layer 10, or a maximum electric field intensity in the interface between semiconductor layer 10 and the oxide film (insulating film portion 15b) can be lowered to less than dielectric breakdown electric field intensity in semiconductor layer 10 or the oxide film (insulating film portion 15b). That is, the semiconductor device according to this embodiment can achieve an improved breakdown voltage without an increase in area of upper surface 10a of semiconductor layer 10 (stated from a different viewpoint, an increase in area of a terminal region OR provided to surround the periphery of an element region IR).

(2) In the semiconductor device according to the embodiment of the present invention, protecting film 1 may be an insulating film. In this configuration, if guard ring regions 3 serving as a terminal structure are provided on upper surface 10a in semiconductor layer 10, a depletion layer can be readily increased in semiconductor layer 10. As a result, the electric field intensity can be alleviated more effectively, whereby a semiconductor device having a high breakdown voltage can be provided.

(3) In the semiconductor device according to the embodiment of the present invention, protecting film 1 may be a multilayered film. In this configuration, by selecting an appropriate material forming protecting film 1, protecting film 1 can have a function other than alleviating the maximum electric field intensity in semiconductor layer 10. For example, protecting film 1 can improve moisture resistance of the semiconductor device by including a layer made of silicon nitride (SiN) or the like.

(4) In the semiconductor device according to the embodiment of the present invention, protecting film 1 may be formed by stacking a silicon nitride film and a silicon oxide film on each other. In this case, for example, a silicon oxide film may be formed as a lower layer in contact with semiconductor layer 10, and a silicon nitride film may be formed on this silicon oxide film. With this configuration, a semiconductor device having a high breakdown voltage and high moisture resistance can be provided, as described above.

(5) In the semiconductor device according to the embodiment of the present invention, end surface 5c may be provided with a step portion 5a, and protecting film 1 may extend from over upper surface 10a to over step portion 5a. Again in this configuration, the distance from the upper electrode (source electrode 16) to the outer peripheral edge of the region covered with protecting film 1 in semiconductor layer 10 can be increased. Thus, in the semiconductor device according to the embodiment, the maximum electric field intensity in semiconductor layer 10 can be suppressed.

(6) In the semiconductor device according to the embodiment of the present invention, protecting film 1 preferably covers the entire end surface 5c. In this configuration, the distance from the upper electrode (source electrode 16) to the outer peripheral edge (end surface 5c) of the region covered with protecting film 1 can be further increased. As a result, the maximum electric field intensity in semiconductor layer 10 can be suppressed more effectively.

(7) In the semiconductor device according to the embodiment of the present invention, a lower electrode (a drain electrode 19) may be formed on a backside surface (a backside surface 10b or a backside surface 12b) of semiconductor layer 10 located opposite to upper surface 10a, the lower electrode being electrically connected to semiconductor layer 10.

In such a vertical type semiconductor device, even if a high voltage is applied between the upper electrode (source electrode 16) and the lower electrode (drain electrode 19), the maximum electric field intensity in semiconductor layer 10 can be alleviated by protecting film 1 formed to extend from upper surface 10a onto at least a portion of end surface 5c with respect to semiconductor layer 10 located between the upper electrode and the lower electrode and electrically connected to both electrodes. As a result, a semiconductor device having an improved breakdown voltage can be provided without an increase in size.

(8) In the semiconductor device according to the embodiment of the present invention, a semiconductor material forming semiconductor layer 10 is a wide band gap semiconductor. In this configuration where the material forming semiconductor layer 10 is a wide band gap semiconductor, even if a high voltage is applied between the upper electrode (source electrode 16) and semiconductor layer 10, the maximum electric field intensity in semiconductor layer 10 can be suppressed in the semiconductor device according to the embodiment since protecting film 1 is formed as described above.

(9) A method of manufacturing a semiconductor device according to an embodiment of the present invention includes the steps of preparing a semiconductor layer 10 having an upper surface 10a (S10), forming an upper electrode (a source electrode 16) on upper surface 10a, the upper electrode being electrically connected to semiconductor layer 10 (S20), forming a trench 5 (a trench enclosed with a step portion 5a and end surfaces 5c with a dicing line at the center between adjacent semiconductor devices; the same being applied hereinafter) in semiconductor layer 10, the trench having a side surface (end surface 5c) intersecting with upper surface 10a (S30), forming a protecting film 1 from over at least a portion of upper surface 10a to over at least a portion of end surface 5c (S40), and dicing semiconductor layer 10 in trench 5 (S50).

In this configuration, prior to the dicing step (S50), trench 5 along the dicing line is formed to include the side surface (end surface 5c) intersecting with a main surface 12a, and protecting film 1 is formed from upper surface 10a onto at least a portion of end surface 5c located in trench 5. Thus, the semiconductor device according to this embodiment can be readily provided.

(10) The method of manufacturing a semiconductor device according the embodiment of the present invention may further include the step of forming a lower electrode (a drain electrode 19) on a backside surface (a backside surface 10b or a backside surface 12b) of semiconductor layer 10 located opposite to upper surface 10a, the lower electrode being electrically connected to semiconductor layer 10. In a vertical type semiconductor device thus provided, even if a high voltage is applied between the upper electrode (source electrode 16) and the lower electrode (drain electrode 19), the maximum electric field intensity in semiconductor layer 10 can be alleviated by protecting film 1 formed to extend from upper surface 10a onto at least a portion of end surface 5c with respect to semiconductor layer 10 located between the upper electrode and the lower electrode (drain electrode 19) and electrically connected to both electrodes. As a result, a semiconductor device capable of achieving an improved breakdown voltage can be provided without an increase in size.

(11) The method of manufacturing a semiconductor device according to the embodiment of the present invention may further include the step of grinding the backside surface (backside surface 10b) before the step of forming a lower electrode (drain electrode 19). Backside surface 12b of semiconductor layer 10 can thus be exposed. Here, if end surface 5c includes a portion on which protecting film 1 has not been formed, backside surface 10b can be ground until that portion is removed, thereby providing a semiconductor device where the entire end surface 5c is covered with protecting film 1. In this configuration, a depletion layer can be more readily increased at end surface 5c of semiconductor layer 10. As a result, the maximum electric field intensity in semiconductor layer 10 can be alleviated more effectively.

### Details of Embodiments of the Present Invention

The details of the embodiments of the present invention will now be described.

### First Embodiment

Referring to FIGS. 1 and 2, a semiconductor device 100 according to a first embodiment is described. While FIG. 2 is a top view of semiconductor device 100 shown in FIG. 1, it illustrates the positional relation between an element region IR and a terminal region OR as well as the configuration of terminal region OR, and does not show the details of element region IR. FIG. 1 shows a cross-sectional view taken along line I-I in FIG. 2. MOSFET 100 as an example of the semiconductor device in the first embodiment mainly includes a semiconductor layer 10, a gate insulating film 15a, a source electrode 16, a gate electrode 17, a drain electrode 19, an interlayer insulating film 71, a source wire 20, a gate wire 21, and a protecting film 1.

Semiconductor layer 10 is made of hexagonal silicon carbide having a polytype of 4H, for example. An upper surface 10a of semiconductor layer 10 may be, for example, a surface having an off angle of about 8° or less relative to a {0001} plane, or may be a surface having a plane orientation of {0-33-8}. Semiconductor layer 10 includes element region IR in a central portion on upper surface 10a, and includes terminal region OR that surrounds element region IR.

Semiconductor layer 10 includes a base substrate 11 and an epitaxial layer 12 in element region IR. Base substrate 11 is a silicon carbide single-crystal substrate made of silicon carbide and having n type conductivity (first conductivity type). Base substrate 11 has a thickness of 50 μm or more and 500 μm or less, for example. Epitaxial layer 12 is an epitaxial layer disposed on base substrate 11, and mainly includes a drift region 12d, p body regions 13 having p type conductivity (second conductivity type), source regions 14 having n type conductivity, and p+ regions 18. Epitaxial layer 12 has a film thickness of 10 μm or more and 50 μm or less, for example. Drift region 12d has n type conductivity, and contains an impurity such as nitrogen (N). A nitrogen concentration in drift region 12d is about 5×10¹⁵ cm⁻³, for example. Drift region 12d includes a JFET region sandwiched between a pair of p body regions 13 which will be described later.

In terminal region OR, semiconductor layer 10 mainly includes a JTE (Junction Termination Extension) region 2, guard ring regions 3, and a field stop region 4. JTE region 2, guard ring regions 3, and field stop region 4 are all in contact with upper surface 10a. JTE region 2 has p type conductivity, and is connected to p body regions 13. An impurity concentration in JTE region 2 is set to be lower than an impurity concentration in p body regions 13 which will be described later, for example. Guard ring regions 3 have p type conductivity, and are separated from p body regions 13. An impurity concentration in guard ring regions 3 is set to be substantially equal to the impurity concentration in JTE region 2, for example. A plurality of guard ring regions 3 having an annular shape in plan view are formed while being separated by epitaxial layer 12 in semiconductor layer 10. For example, there are formed a guard ring region 3a, and a guard ring region 3b that surrounds guard ring region 3a. Field stop region 4 has n type conductivity. An impurity concentration in field stop region 4 is set to be higher than the impurity concentration in drift region 12d (or epitaxial layer 12). Referring to FIG. 2, field stop region 4 is disposed on the outer side relative to guard ring regions 3 on upper surface 10a of semiconductor layer 10.

Referring to FIGS. 1 and 2, an end surface 5c located on the outer side relative to field stop region 4 on upper surface 10a of semiconductor layer 10 is provided with a step portion 5a. Specifically, at an outer peripheral edge of semiconductor layer 10, the end surface intersecting with upper surface 10a is provided with step portion 5a. Step portion 5a is formed in base substrate 11 of semiconductor layer 10. The end surface of semiconductor layer 10 includes end surfaces 5c, 10c, and step portion 5a.

Protecting film 1 extends from over upper surface 10a to over step portion 5a. Specifically, protecting film 1 is formed over an insulating film portion 15b and interlayer insulating film 71 which will be described later, on upper surface 10a. Further, protecting film 1 is formed in contact with base substrate 11 and epitaxial layer 12 on end surface 5c and step portion 5a. Protecting film 1 is not formed on end surface 10c intersecting with step portion 5a, thus exposing base substrate 11. Protecting film 1 on upper surface 10a has a thickness of 0.5 μm or more and 2.5 μm or less, for example, and preferably 0.8 μm or more and 2.0 μm or less. A material forming protecting film 1 is preferably a material having an insulating property, and is, for example, silicon dioxide (SiO₂). More preferably, protecting film 1 is formed as a multilayered film. In this case, protecting film 1 is formed in contact with interlayer insulating film 71. A material forming a lower film is SiO₂, for example, and a material forming an upper film formed on the lower film is SiN, for example.

Each of p body regions 13 is in contact with drift region 12d, and includes upper surface 10a. P body region 13 has p type conductivity (second conductivity type). P body region 13 contains an impurity (acceptor) such as aluminum or boron. An acceptor concentration in p body region 13 is about 4×10¹⁶ cm⁻³ or more and 2×10¹⁸ cm⁻³ or less, for example. The impurity (acceptor) concentration in p body region 13 is higher than the impurity (donor) concentration in drift region 12d. P body region 13 is connected to JTE region 2 as described above.

Each of source regions 14 is in contact with body region 13 and upper surface 10a, and is separated from drift region 12d by body region 13. Source region 14 is formed so as to be surrounded by body region 13. Source region 14 has n type conductivity. Source region 14 contains an impurity (donor) such as phosphorus (P). An impurity (donor) concentration in source region 14 is about 1×10¹⁸ cm⁻³, for example. The impurity (donor) concentration in source region 14 is higher than the impurity (acceptor) concentration in p body region 13, and higher than the impurity (donor) concentration in drift region 12d.

Each of p+ regions 18 includes upper surface 10a, and is disposed in contact with source region 14 and body region 13. P+ region 18 is formed so as to be surrounded by source region 14 and to extend from upper surface 10a into body region 13. P+ region 18 is a p type region containing an impurity (acceptor) such as Al. An impurity (acceptor) concentration in p+ region 18 is higher than the impurity (acceptor) concentration in body region 13. The impurity (acceptor) concentration in p+ region 18 is about 1×10²⁰ cm⁻³, for example.

Gate insulating film 15a is disposed in contact with body regions 13 and drift region 12d on upper surface 10a of semiconductor layer 10. Gate insulating film 15a is made of silicon dioxide (SiO₂), for example. Here, gate insulating film 15a has a thickness of about 45 nm or more and 70 nm or less, for example. In addition, insulating film portion 15b made of the same material and having the same thickness as gate insulating film 15a may be formed on upper surface 10a so as to be in contact with JTE region 2, guard ring regions 3, and field stop region 4.

Gate electrode 17 is disposed to face body regions 13 and drift region 12d, with gate insulating film 15a interposed therebetween. Gate electrode 17 is disposed in contact with gate insulating film 15a so as to sandwich gate insulating film 15a between itself and semiconductor layer 10. Gate electrode 17 is made of a conductor such as polysilicon doped with an impurity, or a metal such as aluminum (Al).

Source electrode 16 is disposed in contact with source regions 14, p+ region 18, and gate insulating film 15a. Source electrode 16 is made of a material capable of making ohmic contact with source regions 14, such as NiSi (nickel silicide). Source electrode 16 may be made of a material including titanium (Ti), aluminum (Al) and silicon (Si).

Drain electrode 19 is formed in contact with a backside surface 10b of semiconductor layer 10. This drain electrode 19 is made of a material capable of making ohmic contact with n type base substrate 11, such as NiSi, and is electrically connected to base substrate 11.

Interlayer insulating film 71 is formed so as to be in contact with gate insulating film 15a and to surround gate electrode 17. That is, interlayer insulating film 71 is provided with a first opening in a region located over gate electrode 17. Interlayer insulating film 71 is also provided with a second opening in a region located over the source electrode. Interlayer insulating film 71 is made of silicon dioxide which is an insulator, for example. Source wire 20 is provided on interlayer insulating film 71 in a position facing upper surface 10a of semiconductor layer 10. Source wire 20 is made of a conductor such as Al, and is connected to source electrode 16 through the second opening. Source wire 20 is also electrically connected to source regions 14 with source electrode 16 interposed therebetween. Gate wire 21 is provided on interlayer insulating film 71, and is electrically connected to gate electrode 17 through the first opening.

The operation of MOSFET 100 is now described. Referring to FIG. 1, when a voltage of gate electrode 17 is lower than a threshold voltage, namely, in an off state, a pn junction between p body region 13 located immediately below gate insulating film 15a and drift region 12d is reverse biased, resulting in a non-conducting state. When a voltage equal to or higher than the threshold voltage is applied to gate electrode 17, on the other hand, an inversion layer is formed in a channel region near an area where p body region 13 and gate insulating film 15a are in contact with each other. As a result, source region 14 and drift region 12d are electrically connected to each other via the channel region, causing a current to flow between source wire 20 and drain electrode 19.

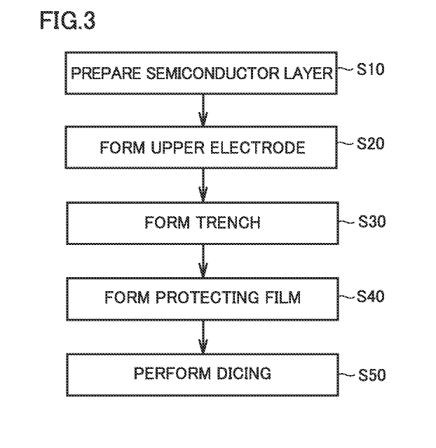

An example of a method of manufacturing MOSFET 100 in this embodiment is now described with reference to FIGS. 2 to 7.

First, semiconductor layer 10 is prepared (step (S10)). Specifically, base substrate 11 is first prepared. Base substrate 11 made of hexagonal silicon carbide having a polytype of 4H, for example, is prepared, and epitaxial layer 12 including n type (first conductivity type) drift region 12d is formed on base substrate 11 by epitaxial growth. Drift region 12d contains an impurity such as N (nitrogen) ions. Epitaxial layer 12 has a film thickness of 10 μm or more and 50 μm or less, for example.

Next, impurities are selectively implanted into epitaxial layer 12 using a mask layer or the like as a mask, to form p body regions 13, source regions 14, and p+ regions 18 in element region IR of epitaxial layer 12. Further, JTE region 2, guard ring regions 3 and field stop region 4 are formed in terminal region OR. Specifically, p body regions 13, JTE region 2 and guard ring regions 3 having p type conductivity are formed by implanting Al ions, for example, as a p type impurity into epitaxial layer 12 having n type conductivity. Further, source regions 14 and field stop region 4 having n type conductivity are formed by implanting phosphorus (P) ions, for example, as an n type impurity.

Next, heat treatment is carried out for activating the impurities implanted through the ion implantations. A temperature of the heat treatment is preferably 1500° C. or more and 1900° C. or less, and is about 1700° C., for example. A time of the heat treatment is about 30 minutes, for example. An atmosphere of the heat treatment is preferably an inert gas atmosphere, and is an argon (Ar) atmosphere, for example. In this manner, semiconductor layer 10 is prepared in this step (S10).

Next, an insulating film 15 is formed. Specifically, insulating film 15 made of silicon dioxide is formed on the aforementioned upper surface 10a of semiconductor layer 10 by thermal oxidation of semiconductor layer 10 which now has the impurity regions formed through the ion implantations. Insulating film 15 includes gate insulating film 15a provided in a position facing a channel region CH formed in p body regions 13, and insulating film portion 15b in contact with JTE region 2, guard ring regions 3, and field stop region 4. The thermal oxidation can be performed by heating semiconductor layer 10 to about 1300° C. in an oxygen atmosphere, for example, and holding it for about 40 minutes. Insulating film 15 is provided with an opening in a region where source electrode 16 is to be formed, by etching using a mask.

Next, gate electrode 17 is formed. In this step, a conductor layer made of polysilicon or Al which is a conductor, for example, is formed on gate insulating film 15a with a conventionally well-known method. When polysilicon is employed as a material for gate electrode 17, the polysilicon can be included at a high concentration where P exceeds 1×10²⁰ cm⁻³. Then, an insulating film made of SiO₂, for example, is formed to cover gate electrode 17.

Next, an ohmic electrode is formed (step (S20)). Specifically, a resist pattern having an opening to partially expose p+ region 18 and source regions 14 is formed, for example, and a metal film containing Si atoms, Ti atoms and Al atoms is formed in this state on an upper surface of the resist pattern and in the aforementioned opening. The metal film to become the ohmic electrode is formed by sputtering or vapor deposition, for example. The resist pattern is then lifted off, for example, to form a metal film in contact with gate insulating film 15a, and also in contact with p+ region 18 and source regions 14. Then, the metal film is heated to about 1000° C., for example, to form source electrode 16 in ohmic contact with semiconductor layer 10. Here, drain electrode 19 may be formed in ohmic contact with base substrate 11 of semiconductor layer 10 by sputtering or vapor deposition in a similar manner.

Next, interlayer insulating film 71 is formed. Specifically, a layer to become interlayer insulating film 71 is formed on insulating film 15, source electrode 16, and gate electrode 17. This layer is formed of an insulating film made of SiO₂, for example, by CVD. Then, a resist having openings in regions located over source electrode 16 and gate electrode 17 is formed on the layer to become interlayer insulating film 71. Portions of this layer to become interlayer insulating film 71 which are exposed at the openings of the resist are removed by etching or the like to form first and second openings, thereby partially exposing source electrode 16 and gate electrode 17. In this manner, interlayer insulating film 71 at which source electrode 16 and gate electrode 17 are partially exposed can be formed.

Next, a wire is formed. Specifically, source wire 20 electrically connected to source electrode 16 exposed at interlayer insulating film 71 is formed by vapor deposition and with a lift-off process, for example. Further, gate wire 21 electrically connected to gate electrode 17 exposed at interlayer insulating film 71 is formed by vapor deposition and with a lift-off process, for example.

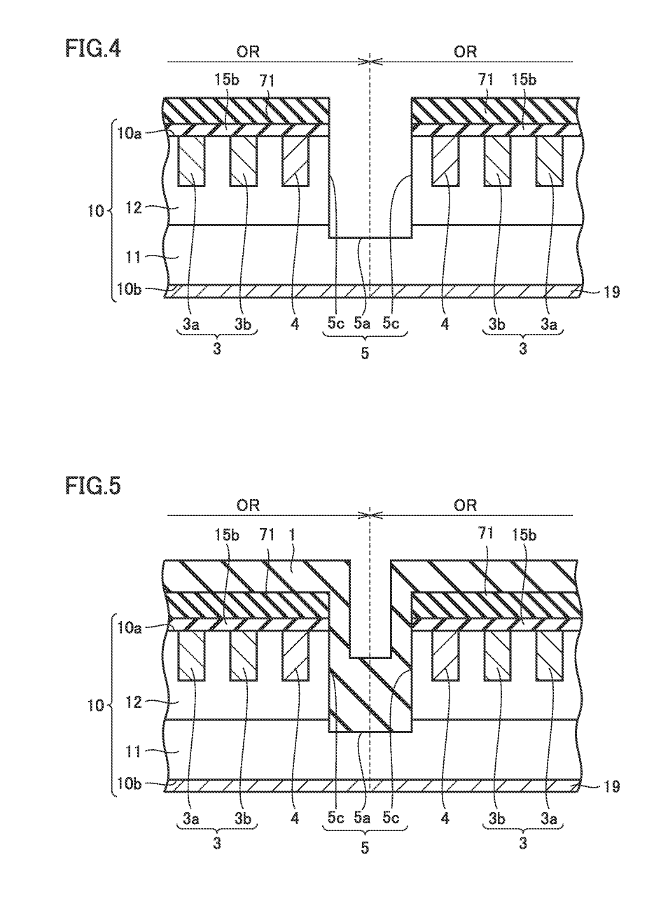

Referring now to FIG. 4, a trench 5 is formed (step (S30)). Specifically, semiconductor layer 10 is partially ground from the upper surface 10a side, for example, along a dicing line arranged to surround terminal region OR. As a result, trench 5 having a bottom surface and a sidewall is formed in semiconductor layer 10. The bottom surface of trench 5 includes step portion 5a, and the sidewall of trench 5 includes end surface 5c shown in FIG. 1. Here, it is preferred that trench 5 have a depth of 30 μm or more in a direction perpendicular to upper surface 10a, for example. That is, in this step, it is preferred that the sidewall (end surface 5c) of trench 5 be formed to reach base substrate 11. In addition, trench 5 may have any width, which may be greater than a total value of the thickness twice the thickness of protecting film 1 and an amount of processing in the dicing step. It is also preferred that end surface 5c be provided perpendicular to upper surface 10a. This allows an increase in size of terminal region OR provided on upper surface 10a as compared to when end surface 5c is inclined relative to upper surface 10a, thereby increasing the breakdown voltage of MOSFET 100 more effectively.

Referring now to FIG. 5, protecting film 1 is formed (step (S40)). Specifically, protecting film 1 is formed to extend from over upper surface 10a to over end surface 5c, and the bottom surface including step portion 5a of trench 5. Protecting film 1 is thus formed on insulating film portion 15b and interlayer insulating film 71 so as to extend from element region IR to an outer peripheral edge of terminal region OR. Protecting film 1 is also formed to extend onto epitaxial layer 12 and base substrate 11 which are exposed at end surface 5c and the bottom surface including step portion 5a. That is, in terminal region OR, epitaxial layer 12 is covered with protecting film 1 at upper surface 10a and end surface 5c as well (see FIG. 1).

Next, dicing is performed along trench 5 (step (S50)). Specifically, dicing is performed in trench 5 (more specifically, the bottom surface of trench 5) which was formed along the dicing line arranged to surround terminal region OR in the previous step (S30). Here, the dicing is performed such that protecting film 1 formed on end surface 5c is not removed. In this manner, semiconductor device 100 as a MOSFET is completed.

A function and effect of MOSFET 100 and the method of manufacturing the same according to the first embodiment will now be described.

In MOSFET 100 according to the first embodiment, where protecting film 1 extends from over upper surface 10a to over end surface 5c and step portion 5a, the distance from source electrode 16 to the edge of the region covered with protecting film 1 in semiconductor layer 10 can be increased, as compared to a conventional semiconductor device having the same size and having the protecting film formed only on the upper surface. Specifically, the distance from a point A where source electrode 16 and p body region 13 are in contact with each other to a point C corresponding to the outer peripheral edge of the region covered with protecting film 1 in epitaxial layer 12 of MOSFET 100 (not the distance of a surface extending between point A and point C, but the distance between point A and point C through the inside of epitaxial layer 12) is greater than the distance from point A to a point B in a conventional semiconductor device having the protecting film formed only on the upper surface. This distance is inversely proportional to the intensity of an electric field generated in semiconductor layer 10 when a voltage is applied between the source and drain of MOSFET 100. In this embodiment, therefore, the electric field intensity in semiconductor layer 10 can be suppressed by increasing the aforementioned distance. In particular, the electric field intensity in a portion where p body region 13 and JTE region 2 are in contact with each other can be lowered to less than the dielectric breakdown electric field intensity in the oxide film (insulating film portion 15b) forming an interface with SiC forming semiconductor layer 10 or with semiconductor layer 10, and can be set to 1.8 MV/cm or less, for example. In this manner, MOSFET 100 according to this embodiment can achieve an improved breakdown voltage without an increase in area occupied by terminal region OR provided to surround the periphery of element region IR.

Further, in MOSFET 100 according to the first embodiment, protecting film 1 extends from upper surface 10a onto step portion 5a in terminal region OR, with step portion 5a being provided in base substrate 11. Thus, epitaxial layer 12 is not exposed but covered with protecting film 1 at end surface 5c as well. As a result, a maximum electric field intensity in semiconductor layer 10 can be alleviated as compared to when protecting film 1 is formed only on upper surface 10a of semiconductor layer 10. In particular, the electric field intensity in the portion where p body region 13 and JTE region 2 are in contact with each other can be alleviated more effectively.

### Second Embodiment

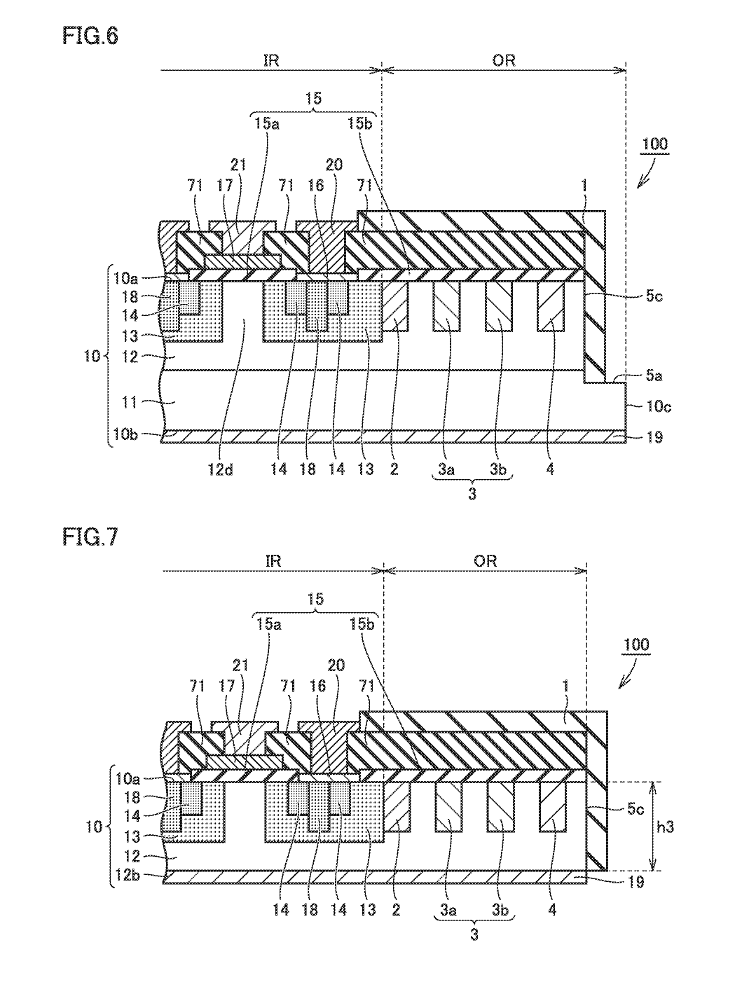

Referring now to FIG. 6, a semiconductor device and a method of manufacturing the same according to a second embodiment will be described. The semiconductor device and the method of manufacturing the same according to the second embodiment are basically similar in configuration to the semiconductor device and the method of manufacturing the same according to the first embodiment, but is different in that protecting film 1 is provided to cover a portion of step portion 5a instead of covering the entire step portion 5a. In the method of manufacturing the semiconductor device according to the second embodiment, for example, after protecting film 1 is formed to extend from over upper surface 10a to over step portion 5a through end surface 5c in a manner similar to the method of manufacturing the semiconductor device according to the first embodiment, protecting film 1 formed on step portion 5a may be partially etched so as to partially expose step portion 5a. Again in this configuration, with protecting film 1 extending from over upper surface 10a to over end surface 5c and over a portion of step portion 5a, the distance from source electrode 16 to the outer peripheral edge of the region covered with protecting film 1 in semiconductor layer 10 can be increased, as compared to a semiconductor device having the same size and having the protecting film formed only on the upper surface. Thus, the maximum electric field intensity in semiconductor layer 10 can be suppressed by increasing the aforementioned distance. In particular, in MOSFET 100 according to this embodiment, the electric field intensity in the portion where p body region 13 and JTE region 2 are in contact with each other can be lowered to less than the dielectric breakdown electric field intensity in the oxide film (insulating film portion 15b) forming an interface with SiC forming semiconductor layer 10 or with semiconductor layer 10, and can be set to 1.8 MV/cm or less, for example.

Moreover, if trench 5 is formed to reach base substrate 11 in the method of manufacturing the semiconductor device according to the second embodiment, since protecting film 1 extends from over upper surface 10a to over a portion of step portion 5a, epitaxial layer 12 is completely covered with protecting film 1 at upper surface 10a and end surface 5c. As a result, the maximum electric field intensity in semiconductor layer 10 can be alleviated more effectively.

### Third Embodiment

Referring now to FIG. 7, a semiconductor device and a method of manufacturing the same according to a third embodiment will be described. The semiconductor device and the method of manufacturing the same according to the third embodiment are basically similar in configuration to the semiconductor device and the method of manufacturing the same according to the first embodiment, but is different in that end surface 10c not covered with protecting film 1 (see FIG. 1) is not formed. Stated from a different viewpoint, the third embodiment is different in that base substrate 11 is removed from semiconductor layer 10, and drain electrode 19 is formed on a backside surface 12b of epitaxial layer 12.

In the method of manufacturing the semiconductor device according to the third embodiment, for example, trench 5 is formed along the dicing line in a manner similar to the method of manufacturing the semiconductor device according to the first embodiment. Then, after protecting film 1 is formed to extend from upper surface 10a onto step portion 5a of end surface 5c, semiconductor layer 10 is diced along trench 5. Then, the backside surface 10b side of diced semiconductor layer 10 is ground or etched, to expose backside surface 12b located opposite to upper surface 10a at epitaxial layer 12. Step portion 5a has now been removed, and the entire end surface 5c has been covered with protecting film 1 at the outer peripheral edge of terminal region OR. Then, drain electrode 19 is formed on backside surface 12b. Again in this configuration, with protecting film 1 extending from upper surface 10a to end surface 5c and a portion of step portion 5a, the distance from source electrode 16 to the region covered with protecting film 1 in semiconductor layer 10 can be increased, as compared to a semiconductor device having the same size and having the protecting film formed only on the upper surface. Thus, the maximum electric field intensity in semiconductor layer 10 can be suppressed by increasing the aforementioned distance. In particular, in MOSFET 100 according to this embodiment, the electric field intensity in the portion where p body region 13 and JTE region 2 are in contact with each other can be lowered to less than the dielectric breakdown electric field intensity in the oxide film (insulating film portion 15b) forming an interface with SiC forming semiconductor layer 10 or with semiconductor layer 10, and can be set to 1.8 MV/cm or less, for example. It is noted that the removal of base substrate 11 from the backside surface 10b side of semiconductor layer 10 can be carried out with any method, which is not limited to grinding or etching.

While the material forming semiconductor layer 10 is hexagonal silicon carbide having a polytype of 4H in the semiconductor devices according to the first to third embodiments described above, the material is not limited thereto. For example, hexagonal silicon carbide having a polytype of 6H may be employed. In addition, the material forming semiconductor layer 10 may be any wide band gap semiconductor, and may be, for example, gallium nitride (GaN) or diamond. Again in this configuration, a similar effect to that of the semiconductor devices and the methods of manufacturing the same according to the first to third embodiments can be provided.

While the semiconductor devices according to the first to third embodiments described above are each a planar type MOSFET, the devices are not limited thereto, and may each be a trench type MOSFET, for example. Alternatively, the semiconductor devices may each be a Schottky barrier diode or an IGBT (Insulated Gate Bipolar Transistor), for example.

Although the embodiments of the present invention have been described above, the embodiments described above can be modified in various ways. Further, the scope of the present invention is not limited to the embodiments described above. The scope of the present invention is defined by the terms of the claims, and is intended to include any modifications within the scope and meaning equivalent to the terms of the claims.

### INDUSTRIAL APPLICABILITY

The present invention is applied particularly advantageously to a semiconductor device required to have a high breakdown voltage and a method of manufacturing the same.

### REFERENCE SIGNS LIST

1 protecting film; 2 JTE region; 3 guard ring region; 4 field stop region; 5 trench; 5a step portion; 5c end surface; 10 semiconductor layer; 10a upper surface; 10b backside surface; 10c end surface; 11 base substrate; 12 epitaxial layer; 12a main surface; 12d drift region; 13 p body region; 14 source region; 15 insulating film; 15a gate insulating film; 15b insulating film portion; 16 source electrode; 17 gate electrode; 19 drain electrode; 20 source wire; 21 gate wire; 71 interlayer insulating film; 100 MOSFET; IR element region; OR terminal region.

1. A semiconductor device comprising:
a semiconductor layer having an upper surface and an end surface intersecting with said upper surface;
an upper electrode formed on said upper surface and electrically connected to said semiconductor layer; and
a protecting film extending from over at least a portion of said upper surface to over at least a portion of said end surface.

2. The semiconductor device according to claim 1, wherein
said protecting film is an insulating film.

3. The semiconductor device according to claim 1, wherein
said protecting film is a multilayered film.

4. The semiconductor device according to claim 3, wherein
said protecting film is formed by stacking a silicon nitride film and a silicon oxide film on each other.

5. The semiconductor device according to claim 1, wherein
said end surface is provided with a step portion, and
said protecting film extends from over said upper surface to over said step portion of said end surface.

6. The semiconductor device according to claim 1, wherein
said protecting film covers the entire said end surface.

7. The semiconductor device according to claim 1, wherein
a lower electrode is formed on a backside surface of said semiconductor layer located opposite to said upper surface, said lower electrode being electrically connected to said semiconductor layer.

8. The semiconductor device according to claim 1, wherein
a semiconductor material forming said semiconductor layer is a wide band gap semiconductor.

9. A method of manufacturing a semiconductor device, comprising the steps of:
preparing a semiconductor layer having an upper surface;
forming an upper electrode on said upper surface, said upper electrode being electrically connected to said semiconductor layer;
forming a trench in said semiconductor layer, said trench having a side surface intersecting with said upper surface;
forming a protecting film from over at least a portion of said upper surface to over at least a portion of said end surface; and
dicing said semiconductor layer in said trench.

10. The method of manufacturing a semiconductor device according to claim 9, further comprising the step of forming a lower electrode on a backside surface of said semiconductor layer located opposite to said upper surface, said lower electrode being electrically connected to said semiconductor layer.

11. The method of manufacturing a semiconductor device according to claim 10, further comprising the step of grinding said backside surface before said step of forming a lower electrode.
